(19) United States
(12) Patent Application Publication
(10) Pub. No.: US 2023/0383122 A1
(43) Pub. Date: Nov. 30, 2023

(54) COVER FILM AND IMAGE DISPLAY DEVICE INCLUDING THE SAME

(71) Applicants: LG DISPLAY CO., LTD., Seoul (KR); Sanyo Chemical Industries, Ltd., Kyoto (JP); Bando Chemical Industries, Ltd., Hyogo (JP)

(72) Inventors: Harumi OKUNO, Kanagawa (JP); Takayuki OTA, Kanagawa (JP); Masafumi SAWADA, Kyoto (JP); Atsushi WAKATSUKI, Kyoto (JP); Yutaka KAMADA, Hyogo (JP)

(73) Assignees: LG DISPLAY CO., LTD., Seoul (KR); Sanyo Chemical Industries, Ltd., Kyoto (JP); Bando Chemical Industries, Ltd., Hyogo (JP)

(21) Appl. No.: 18/203,962

(22) Filed: May 31, 2023

(30) Foreign Application Priority Data
May 31, 2022 (JP) 2022-088915

(51) Int. Cl. C08L 75/08; H05K 5/03

(52) U.S. Cl. CPC C08L 75/08; H05K 5/03; C08L 2203/16; C08L 2205/025; C08L 2312/00

(57) ABSTRACT

Cover film has a base material layer and a surface layer chemically bonded to the base material layer, where the surface layer includes a polyurethane resin X1 containing urethane and urea units and a polyorganosiloxane group in the molecule, the polyurethane resin X1 is a reaction product of a non-yellowing-type isocyanate component B1 with an active hydrogen component A1 including a compound a1-1, the base material layer includes a polyurethane resin X2 having a urethane bond in the molecule, and the polyurethane resin X2 is a reaction product of a non-yellowing-type isocyanate component B2 with an active hydrogen component A2 which does not include the compound a1-1, and has a certain crosslinking point concentration and also has a certain elastic recovery rate.

### CROSS-REFERENCE TO RELATED APPLICATIONS

This application claims the benefit under 35 U.S.C. § 119(a) of Japanese Patent Application No. 2022-088915, filed on May 31, 2022, in the Japanese Intellectual Property Office, which is incorporated herein by reference in its entirety.

### BACKGROUND

### 1. Technical Field

The present disclosure relates to a cover film and an image display device including the same.

### 2. Discussion of the Related Art

In addition to image display devices having flexibility (bendability, foldability, or rollability), image display devices showing stretchability have recently been under development as portable image display devices such as smartphone, tablet PCs, or the like (Japanese Patent Laid-Open Publication Nos. 2015-152922 and 2020-102065).

Such an image display device has a cover window configured to protect an image display element such as an organic EL display, an LED display, a liquid crystal display, and the like. In recent years, many portable image display devices have been using a cover window including a glass base material. However, because the glass base material is easily broken by external impact and has no flexibility, it is not applicable to image display devices having flexibility (hereinafter also referred to as “flexible displays”) or image display devices having stretchability (hereinafter also referred to as “stretchable displays”). Accordingly, replacing the glass base material with a resin film (i.e., a cover film) rather than a glass substrate is under examination, and image display devices using a polyimide-based film having transparency as a cover film are known.

When a cover film is used as a surface protection material of an image display device, the cover film needs to have proper lubricity (scratch resistance) and mechanical properties (hardness) in addition to the transparency. Also, when the cover film has a small curvature radius in the flexible display, it is desirable that the cover film be more flexible. Meanwhile, when the surface protection material is used as the cover film of the stretchable display, it needs to have excellent stretchability as well. Because a conventional polyimide-based film has no stretchability, it is difficult to apply the polyimide-based film to stretchable displays. For this challenge, for example, Japanese Patent Laid-Open Publication No. 2020-042981 discloses using an elastomer showing stretchability as the cover film.

However, the cover film having stretchability has a problem in that it does not have sufficient scratch resistance. A technique for coating a hard coat layer with a material having lubricity in order to improve the scratch resistance is also known, but it is not possible to meet the scratch resistance standards for the flexible displays or the stretchable displays even by this method. Also, there is a problem in that the film is cracked when the image display device is stretched. Further, a technique for coating a surface of the film has new problems such as coatability (plating) or close adhesion to films to be used as a base material.

### SUMMARY

Accordingly, embodiments of the present disclosure are directed to a cover film and an image display device including the same that substantially obviate one or more of the problems associated with the limitations and disadvantages of the related art.

An object of the present disclosure is to provide a cover film having excellent scratch resistance, mechanical properties and optical properties and also having excellent stretchability, and an image display device including the cover film.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is cover film comprising: a base material layer; and a surface layer installed on at least one surface of the base material layer, wherein the base material layer and the surface layer are chemically bonded to each other, wherein the surface layer includes a polyurethane resin X1 having urethane and urea units and a polyorganosiloxane group, wherein the polyurethane resin X1 is a reaction product of a non-yellowing-type isocyanate component B1 with an active hydrogen component A1, wherein the active hydrogen component A1 includes a compound a1-1 containing a polyorganosiloxane group and an active hydrogen group, and a ratio of the compound a1-1 to the sum (100 wt %) of the active hydrogen component A1 and the non-yellowing-type isocyanate component B1 is less than or equal to 4.0 wt %, wherein the base material layer includes a polyurethane resin X2 having a urethane unit, wherein the polyurethane resin X2 is a reaction product of a non-yellowing-type isocyanate component B2 with an active hydrogen component A2 which does not comprise the compound a1-1, wherein a crosslinking point concentration of the polyurethane resin X2 calculated from the following Equation 1 is greater than or equal to 0.4 mmol/g, [Equation 1] Crosslinking point concentration (mmol/g)=(F−2)*(mmol of 3 or more functional constituent monomers in 1 g of polyurethane resin), wherein in the Equation 1, F denotes the number of functional groups in a trifunctional or higher functional constituent monomer, and wherein an elastic recovery rate of the cover film when 100% stretched is in a range of 80% to 100%.

It is to be understood that both the foregoing general description and the following detailed description are exemplary and explanatory and are intended to provide further explanation of the inventive concepts as claimed.

### DETAILED DESCRIPTION

Hereinafter, exemplary embodiments of the present disclosure will be described in detail. The present disclosure is not limited to the following embodiments, and may be realized in various forms without departing from the scope of the present disclosure.

In this specification, the symbol “-” when used in a range represents the term “to.”

[Cover Film]

A cover film according to this embodiment includes a base material layer and a surface layer disposed (installed) on at least one surface of the base material layer. The base material layer and the surface layer are chemically bonded to each other via a chemical bond. The surface layer includes a polyurethane resin X1 (e.g., a first polyurethane resin) having a urethane unit (or bond), a urea unit and a polyorganosiloxane group in the molecule, and the polyurethane resin X1 is a reaction product of a non-yellowing-type isocyanate component B1 (e.g., a first non-yellowing-type isocyanate component) with an active hydrogen component A1 (e.g., a first active hydrogen component). The active hydrogen component A1 includes a compound a1-1 containing a polyorganosiloxane group and an active hydrogen group, and a ratio of the compound a1-1 to the sum (100 wt %) of the active hydrogen component A1 and the non-yellowing-type isocyanate component B1 is 4.0 wt % or less. The base material layer includes a polyurethane resin X2 (e.g., a second polyurethane resin) having a urethane bond in the molecule, and the polyurethane resin X2 is a reaction product of a non-yellowing-type isocyanate component B2 (e.g., a second non-yellowing-type isocyanate component) with an active hydrogen component A2 (e.g., a second active hydrogen component), which does not include the compound a1-1. A crosslinking point concentration of the polyurethane resin X2 calculated from the following Equation 1 is 0.4 mmol/g or more, and an elastic recovery rate of the cover film is in a range of 80% to 100% when 100% stretched.

Crosslinking point concentration (mmol/g)=(F−2)*(mmol of 3 or more functional constituent monomers in 1 g of polyurethane resin) [Equation 1]

The cover film according to this embodiment has excellent scratch resistance, mechanical properties and optical properties and also has excellent stretchability. Hereinafter, the cover film according to the present disclosure will be described in detail.

<Surface Layer>

The cover film according to this embodiment has a base material layer and a surface layer disposed on at least one surface of the base material layer. The surface layer includes a polyurethane resin X1 having a urethane unit and a urea unit and a polyorganosiloxane group in the molecule. The surface layer is chemically bonded to a base material layer as will be described below. Here, the term “chemically bonded” refers to a state in which a component constituting the surface layer and a component constituting the base material layer chemically react with each other so that they are chemically connected to each other at the interface thereof. Because the cover film has such a configuration, interlaminar delamination is difficult when stress is applied to the cover film. As a result, the scratch resistance and mechanical properties are improved. Also, when the surface layer includes the polyurethane resin X1 containing the urethane bond and the urea bond in the molecule, the scratch resistance of the surface layer may be improved and the proper hardness may also be expressed.

(Polyurethane Resin X1)

The polyurethane resin X1 included in the surface layer is a reaction product of a non-yellowing-type isocyanate component B1 (hereinafter also referred to as a component B1) with an active hydrogen component A1 (hereinafter also referred to as a component A1). In this specification, “non-yellowing-type isocyanate” and “non-yellowing isocyanate” refer to an isocyanate compound which does not include an aromatic component.

The active hydrogen component A1 includes a compound a1-1 containing a polyorganosiloxane group and an active hydrogen group. The ratio of the compound a1-1 to the sum (100% wt %) of the component A1 and the component B1 is 4.0 wt % or less. When the surface layer includes the polyurethane resin X1, the scratch resistance and mechanical properties are improved.

[Active Hydrogen Component A1]

The active hydrogen component A1 may be an component that includes a compound a1-1 (hereinafter referred to as a compound a1-1) containing a polyorganosiloxane group and an active hydrogen group.

<Compound a1-1>

The compound a1-1 is a compound having a polyorganosiloxane group and an active hydrogen group. When a reaction product of the component B1 with the component A1 including the compound a1-1 is used in the surface layer, the scratch resistance of the surface layer may be enhanced.

The active hydrogen group included in the compound a1-1 may include at least one active hydrogen group selected from a hydroxyl group, an amino group, and a carboxyl group, and preferably the amino group. When the compound a1-1 contains the amino group as an active hydrogen group, a polyurethane resin X1 including a urea bond in the molecule may be easily obtained. Also, the urea bond in the polyurethane resin X1 may be formed by the reaction of the component B1 with a component included in the component A1 other than the compound a1-1.

The polyorganosiloxane group of the compound a1-1 may have a structure represented by the following Formula (I).

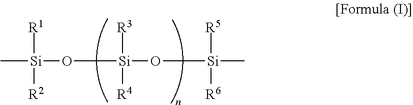

In Formula (I), each of R¹ to R⁶ is independently selected from the group consisting of a C1 to C6 linear alkyl group and a C1 to C6 branched alkyl group, and n is an integer of 1 to 100.

In an aspect of the present disclosure, each of R¹ to R⁶ may be a C1 to C3 linear alkyl group, preferably methyl, to improve the mechanical properties of the surface layer. Also, n may be an integer ranging of 10 to 70, and preferably an integer of 15 to 50, to improve the mechanical properties of the surface layer and the haze value of the cover film. “C1 to C10 linear alkyl group” may be methyl, ethyl, or n-propyl.

The compound a1-1 may have the polyorganosiloxane group represented by Formula (I), and also have an active hydrogen group at one or more of one or both lateral ends of a molecular chain, and side chains. Also, the compound a1-1 more preferably may have hydroxyl group or amino group at one or more of one or both lateral ends of the molecular chain. A commercial product may be used as the compound a1-1.

For example, the commercial product for the compound a1-1 having amino groups at both lateral ends thereof may include at least one selected from the group consisting of the products from Shin-Etsu Chemical Co., Ltd., such as “KF-8010™” (functional group equivalent: 430 g/mol), “X-22-161A™” (functional group equivalent: 800 g/mol), “X-22-161B™” (functional group equivalent: 1,500 g/mol), “KF-8012™” (functional group equivalent: 2,200 g/mol), “KF-8008™” (functional group equivalent: 5,700 g/mol), “X-22-9409™” (functional group equivalent: 700 g/mol), and “X-22-1660B-3™” (functional group equivalent: 2,200 g/mol) (all trade names); and the products from Toray Dow Corning Co., Ltd., such as “BY-16-853U™” (functional group equivalent: 460 g/mol), “BY-16-853™” (functional group equivalent: 650 g/mol), and “BY-16-853B™” (functional group equivalent: 2,200 g/mol) (all trade names). These may be used alone or in combinations of two or more.

For example, the commercial product of the compound a1-1 having hydroxyl groups at both lateral ends thereof may include at least one selected from the group consisting of the products from Shin-Etsu Chemical Co., Ltd., such as “KF-6001™” (functional group equivalent: 900 g/mol), “KF-6002™” (functional group equivalent: 1,600 g/mol), “KF-6003™” (functional group equivalent: 2,550 g/mol), and “X-22-4952™” (functional group equivalent: 1,100 g/mol) (all trade names); and the products from Toray Dow Corning Co., Ltd., such as “SF8427™” (functional group equivalent: 930 g/mol) (trade name). These may be used alone or in combinations of two or more.

For example, the commercial product of the compound a1-1 having a hydroxyl group at one lateral end may include at least one selected from the group consisting of the products from Shin-Etsu Chemical Co., Ltd., such as “X-22-170BX™” (functional group equivalent: 2,800 g/mol), “X-22-170DX™” (functional group equivalent: 4,670 g/mol), “X-22-176DX™” (functional group equivalent: 1,600 g/mol), and “X-22-176F™” (functional group equivalent: 6,300 g/mol) (all trade names). These may be used alone or in combinations of two or more.

Among the commercial products described above, X-22-161A™, BY-16-853U™, and KF-8012™ may be used as the compound a1-1, and BY-16-853U™ and KF-8012™ may be used as the compound a1-1.

The ratio of the compound a1-1 in the polyurethane resin X1 may be less than or equal to 4.0 wt %, may be in a range of 1.0 to 3.0 wt %, and may be in a range of 1.5 to 2.0 wt %, with respect to the sum (100 wt %) of the component A1 and the component B1. When the ratio of the compound a1-1 in the polyurethane resin X1 is less than or equal to 4.0 wt %, the scratch resistance and optical properties of the cover film may not be compatible.

In the conventional cover film described in Japanese Patent Laid-Open Publication No. 2020-042981, a technique for coating a hard coat layer is used to improve the scratch resistance of the film. The coating of the hard coat layer improves the hardness of the film and enhances the scratch resistance of the film, but deteriorates the stretchability of the film. Therefore, it is difficult to apply the conventional cover film to stretchable displays. The inventors of the present disclosure have investigated the lubricity rather than the hardness of the cover film, and found that a resin having a slightly high hardness and excellent lubricity and stretchability is obtained by blending a predetermined amount of the compound a1-1 into the surface layer of the cover film. Further, they have found that the pencil hardness is enhanced by improving the lubricity of the surface layer and a recovery force of the base material layer by using a resin having a high crosslinking point concentration, as will be described below, for the base material layer and providing a structure of the base material layer and the surface layer, which are chemically bonded to each other.

<Other Active Hydrogen Component a1-2>

The component A1 may further include an active hydrogen component a1-2 (hereinafter referred to as a component a1-2) in addition to the compound a1-1. For example, the component a1-2 may include at least one selected from a high-molecular polyol, a chain extending agent, and a reaction stopping agent, as disclosed in International Publication No. 2021/002342, which is incorporated herein by reference. In some embodiments, the component a1-2 may be a high-molecular polyol disclosed in International Publication No. 2021/002342, and may be a polycarbonate polyol, to improve the scratch resistance. Also, the component a1-2 may further include at least one of at least one of water, 1,4-dioal, e.g., 1,4-butanediol, and the like as the chain extending agent. Further, the component a1-2 may further include diethanolamine and the like as the reaction stopping agent.

The ratio of the high-molecular polyol in the component a1-2 may be in a range of 50 to 100 wt %, or in a range of 70 to 100 wt %, with respect to the total mass of the component a1-2. When the ratio of the high-molecular polyol is within this range, the scratch resistance may be more improved.

A content of the component a1-2 in the component A1 may be adjusted so that the sum of the compound a1-1 and the component a1-2 become 100 wt % with respect to the total weight of the component A1.

[Non-Yellowing-Type Isocyanate Component B1]

The non-yellowing-type isocyanate component B1 may be an isocyanate compound which does not include an aromatic component. The component B1 reacts with the component A1 for providing a urethane bond and a urea bond. The component B1 may be a polyisocyanate compound which has at least two isocyanate groups and does not include an aromatic component. Namely, the component B1 may be an aliphatic polyisocyanate compound or an alicyclic polyisocyanate compound.

For example, the aliphatic polyisocyanate compound may be an aliphatic diisocyanate compound, e.g., ethylene diisocyanate, tetramethylene diisocyanate, hexamethylene diisocyanate (hereinafter referred to as “HDI”), dodecamethylene diisocyanate, 2,2,4-trimethylhexamethylene diisocyanate, lysine diisocyanate, 2,6-diisocyanato-methylcaproate, bis(2-isocyanato-ethyl)fumarate, bis(2-isocyanato-ethyl)carbonate or 2-isocyanato-ethyl-2,6-diisocyanato-hexanoate; an aliphatic triisocyanate compound, e.g., 1,6,11-undecane triisocyanate; or 3 or more functional aliphatic polyisocyanate compound, e.g., a modified compound containing a urethane group, a carbodiimide group, an allophanate group, a urea group, a biuret group, a uretdione group, a uretimine group, an isocyanurate group, or an oxazolidone group of the above aliphatic diisocyanate compound or the above aliphatic triisocyanate compound. In an aspect of the present disclosure, the aliphatic polyisocyanate compound may be allophanate-modified HDI (for example, product name: “CORONATE 2793” from Tosoh Corporation), isocyanurate-modified HDI (for example, product name: “DUIRANATE® TLA-100” from Asahi Kasei Corporation) or biuret-modified HDI (for example, product name: “DURANATE® 24A-100” from Asahi Kasei Corporation)]. The aliphatic polyisocyanate compound may be used alone or in combinations of two or more of the aliphatic polyisocyanate compounds.

For example, the alicyclic polyisocyanate compound may be an alicyclic diisocyanate compound such as isophorone diisocyanate (hereinafter referred to as “IPDI”), 4,4′-dicyclohexylmethane diisocyanate (hereinafter referred to as “hydrogenated MDI”), cyclohexylene diisocyanate, methylcyclohexylene diisocyanate, bis(2-isocyanato-ethyl)-4-cyclohexene-1,2-dicarboxylate, 2,5- or 2,6-norbornene diisocyanate, and the like. The alicyclic polyisocyanate compound may be used alone or in combinations of two or more of the alicyclic polyisocyanate compounds.

The non-yellowing-type isocyanate component B1 may include an isocyanate compound b1 having three or more functional groups (hereinafter referred to as a compound b1), may include allophanate-modified HDI or biuret-modified HDI. When the component B1 includes the compound b1, a surface layer having superior heat resistance may be easily obtained. As a result, it is easy to control the adhesion or tacking of the film in flexible displays or stretchable displays, to which the cover film according to this embodiment is applied, at a high temperature. In particular, it is easy to control the adhesion between films when these displays are folded or rolled.

A content of the compound b1 in the component B1 may be in a range of 0.5 to 10 wt %, in a range of 0.5 to 7.5 wt %, or in a range of 0.5 to 5.0 wt %, with respect to the total mass of the component B1.

The ratio of the component B1 in the polyurethane resin X1 is not particularly limited as long as the component B1 has effects according to the present disclosure. In one aspect, the molar ratio of the total amount of the NCO group of the component B1 to the total amount of the active hydrogen group in the component A1 (total amount of NCO group/total amount of active hydrogen group) may be in a range of 1.00 to 1.10, or in a range of 1.00 to 1.05. When the molar ratio is in a range of 1.00 to 1.10, the scratch resistance may be enhanced.

A crosslinking point concentration of the polyurethane resin X1 calculated from the following Equation 1 may be in a range of 0.02 to 0.10 mmol/g, or in a range of 0.04 to 0.08 mmol/g. The crosslinking point concentration of the polyurethane resin X1 may be smaller than the crosslinking point concentration of the polyurethane resin X2. When the crosslinking point concentration is within this range, the scratch resistance may be easily improved.

Crosslinking point concentration (mmol/g)=(F−2)*(mmol of 3 or more functional constituent monomers in 1 g of polyurethane resin) [Equation 1]

In Equation 1, F denotes the number of functional groups in a 3 or more functional constituent monomer.

A concentration of the sum of the urethane unit and the urea unit in the polyurethane resin X1 may be in a range of 1.6 to 2.4 mmol/g, or in a range of 1.8 to 2.2 mmol/g. When the concentration of the sum of the urethane unit and the urea unit is within this range, the scratch resistance may be easily improved. Also, the concentration of the sum of the urethane unit and the urea unit in the polyurethane resin X1 may be calculated from the raw material amounts of the active hydrogen component A1 and the non-yellowing-type isocyanate component B1.

(Method of Preparing Polyurethane Resin X1)

A method of preparing the polyurethane resin X1 according to this embodiment is not particularly limited, and may include i) a method 1 comprising: obtaining a urethane prepolymer using a component A1, a component B1, and optionally an organic solvent; and reacting a chain extending agent with the urethane prepolymer to obtain a polyurethane resin X1, or ii) a method 2 comprising: collectively preparing a component A1, a component B1, and optionally an organic solvent in a batch-type reactor; and reacting them by heating to obtain a polyurethane resin X1.

For example, the details of the method 1 and the method 2 are described in International Publication No. 2021/002342, which is incorporated herein by reference.

As measured by a method that will be described later, the elastic recovery rate when the polyurethane resin X1 is 100% stretched may be in a range of 40 to 100%, or in a range of 50 to 100%. When the elastic recovery rate when the polyurethane resin X1 is 100% stretched is within this range, the scratch resistance may be easily improved.

(Other Components C1)

The surface layer may further include other a component C1 (hereinafter referred to as component C1) in addition to the polyurethane resin X1. For example, the component C1 may include an environmental stabilizing agent (such as an antioxidant, an ultraviolet absorbent or a light stabilizing agent), a plasticizer, an adsorbent, a filler, a release agent, a flame retardant, and the like. These may be used alone or in combinations of two or more.

Among them, the environmental stabilizing agent may be included as the component C1 in terms of easily controlling the deterioration (discoloration and the like) of the cover film with elapsed time and further improving the light fastness and heat resistance as well.

Environmental stabilizing agents include an antioxidant, an ultraviolet absorber, and a light stabilizing agent, as described above.

Examples of the antioxidant may include a hindered phenol compound, e.g., pentaerythrityl-tetrakis[3-(3,5-di-t-butyl-4-hydroxyphenyl)propionate] or octadecyl-3-(3,5-di-t-butyl-4-hydroxyphenyl)propionate; a phosphorus compound, e.g., tris(2,4-di-t-butyl phenyl)phosphite; a sulfur compound, e.g., pentaerythrityl-tetrakis(3-laurylthiopropionate), pentaerythrityl-tetrakis(3-laurylthiopropionate) or dilauryl-3,3′-thiodipropionate. These may be used alone or in combinations of two or more.

Examples of the ultraviolet absorbent may include a benzotriazole compound, e.g., 2-(3,5-di-t-amyl-2-hydroxyphenyl)benzotriazole or 2-(5-methyl-2-hydroxyphenyl)benzotriazole.

Examples of the light stabilizing agent may include a hindered amine compound, e.g., (bis-2,2,6,6-tetramethyl-4-piperidyl)sebacate.

The surface layer may include one or two or more of the above-described environmental stabilizing agents. A content of the environmental stabilizing agent in the surface layer may be in a range of 0.5 to 5.0 wt %, in a range of 1.0 to 5.0 wt %, or in a range of 1.5 to 5.0 wt %, with respect to the total mass of the resin composition constituting the surface layer. When the content of the environmental stabilizing agent in the surface layer is greater than or equal to 0.5 wt %, a cover film with less thermally deterioration as time passes may be easily obtained. In addition, when the content of the environmental stabilizing agent in the surface layer is less than or equal to 5.0 wt %, the yellowing of the film by the environmental stabilizing agent may be suppressed with excellent light fastness and heat resistance of the cover film.

When the surface layer is composed of the above-described polyurethane resin X1 and the environmental stabilizing agent without the component C1, the content of the environmental stabilizing agent in the surface layer is the ratio relative to the sum (100 wt %) of the polyurethane resin X1 and the environmental stabilizing agent.

The surface layer may further include one or more of additives described in International Publication No. 2021/002342, which is incorporated herein by reference.

<Base Material Layer>

In the cover film according to some embodiments, the base material layer includes a polyurethane resin X2 having a urethane unit in the molecule. The polyurethane resin X2 is a reaction product of a non-yellowing-type isocyanate component B2 with an active hydrogen component A2 which does not include the compound a1-1, and is characterized in that the crosslinking point concentration of the polyurethane resin X2 calculated using Equation 1 is greater than or equal to 0.4 mmol/g, and the elastic recovery rate when 100% stretched is in a range of 80% to 100%. When the base material layer includes such a polyurethane resin X2 having an elastic recovery rate in a range of 80% to 100%, the base material layer may become a soft layer having a high recovery force. As a result, the mechanical properties (particularly, pencil hardness) of the cover film may be improved.

(Polyurethane Resin X2)

The polyurethane resin X2 included in the base material layer is a reaction product of a non-yellowing-type isocyanate component B2 (hereinafter referred to as a component B2) with an active hydrogen component A2 (hereinafter referred to as a component A2) which does not include the compound a1-1. The crosslinking point concentration of the polyurethane resin X2 calculated from the following Equation 1 may be greater than or equal to 0.4 mmol/g, in a range of 0.4 to 0.6 mmol/g, or in a range of 0.4 to 0.5 mmol/g. When the crosslinking point concentration of the polyurethane resin X2 using Equation 1 is greater than or equal to 0.4 mmol/g, the mechanical properties (particularly, pencil hardness) of the cover film may be improved.

Crosslinking point concentration (mmol/g)=(F−2)*(mmol of 3 or more functional constituent monomers in 1 g of polyurethane resin) [Equation 1]

In Equation 1, F denotes the number of functional groups in a 3 or more functional constituent monomer in the polyurethane resin X2.

[Active Hydrogen Component A2]

The active hydrogen component A2 does not include the compound a1-1, and may include a high-molecular polyol a2-1 (hereinafter referred to as a component a2-1).

The component a2-1 includes polyols having a number average molecular weight (Mn) of 500 or more, in a rage from 500 to 5,000, or in a range from 800 to 4,000. For example, the high-molecular polyols used for the high-molecular polyol a2-1 are described in International Publication No. 2021/002342, which is incorporated herein by reference. Among then, the high-molecular polyol a2-1 may include polyols in which an alkylene oxide is added to tetra- to octa-functional polyvalent alcohols, e.g., as pentaerythritol, sorbitol, mannitol, sorbitan, diglycerin or dipentaerythritol, and may include polyols in which an alkylene oxide is added to hexa- to octa-functional polyvalent alcohols, e.g., sorbitol, mannitol, sorbitan or dipentaerythritol, in terms of easily adjusting the crosslinking point concentration in the polyurethane resin X2 to 0.4 mmol/g or more. The high-molecular polyols a2-1 may be used alone or in combinations of two or more of the high-molecular polyols.

Also, a polyether polyol may be included as the high-molecular polyol a2-1. For example, the polyether polyol may be a compound in which an alkylene oxide is added to polyols having a number average molecular weight (Mn) or a chemical formula weight of less than 500. The polyether polyols may be used alone or in combinations of two or more of the polyether polyols.

In addition, for example, the alkylene oxide may be a C2 to C12 alkylene oxide, e.g., ethylene oxide, 1,2-propylene oxide, 1,3-propylene oxide, 1,2-butylene oxide, 1,3-butylene oxide or 2,3-butylene oxide, tetrahydrofuran, 3-methyl tetrahydrofuran, styrene oxide, α-olefin oxide or epichlorohydrin. Among them, ethylene oxide and 1,2-propylene oxide or 1,3-propylene oxide may be preferred in terms of the scratch resistance.

In an aspect of the present disclosure, the high-molecular polyol a2-1 may include polyols in which at least one alkylene oxide selected from ethylene oxide, 1,2-propylene oxide, and 1,3-propylene oxide is added to at least one polyvalent alcohol selected from sorbitol, mannitol, sorbitan, and dipentaerythritol.

In one aspect of the present disclosure, the high-molecular polyol a2-1 may include polytetramethylene ether glycol (PTMG) having an Mn of 500 to 2,500.

The ratio of the component a2-1 in the component A2 may be in a range of 70 to 100 wt %, in a range of 75 to 100 wt %, or in a range of 75 to 90 wt %, with respect to the total mass of the component A2. When the ratio of the high-molecular polyol a2-1 is within this range, the scratch resistance may be easily improved.

Also, in this specification, the “Mn” may be, for example, measured under the following conditions by gel permeation chromatography.
Device: Waters Alliance 2695 (commercially available from Waters)
Column: connection of Guardcolumn Super H-L (one) and one each of TSKgel® Super H2000®, TSKgel® SuperH3000, and TSKgel® SuperH4000 (all commercially available from Tosoh Corporation)
Sample solution: 0.25 wt % of THF solution
Solution injection amount: 10 μL
Flow rate: 0.6 mL/min
Measured temperature: 40° C.
Detection device: refractive index detector
Reference material: standard polyethylene glycol

<Other Active Hydrogen Components a2-2>

The component A2 may include an active hydrogen components a2-2 (hereinafter referred to as components a2-2) in addition to the component a2-1. For example, the components a2-2 may include at least one selected from the chain extending agent and the reaction stopping agent described in International Publication No. 2021/002342, which is incorporated herein by reference. The component A2 may include 1,4-butanediol or ethylene glycol, and preferably 1,4-butanediol, in terms of the scratch resistance.

The ratio of the 1,4-butanediol and/or ethylene glycol in the components a2-2 may be in a range of 50 to 100 wt %, and may also be in a range of 70 to 100 wt %, with respect to the total mass of the components a2-2. When the ratio of the 1,4-butanediol and/or ethylene glycol is within this range, the scratch resistance may be further enhanced.

[Non-Yellowing-Type Isocyanate Component B2]

The non-yellowing-type isocyanate component B2 is an isocyanate compound that does not including an aromatic component. The component B2 reacts with the component A2 to form a urethane bond. Examples of the component B2 may include the same polyisocyanates as the component B1. The component B2 preferably includes HDI or isophorone diisocyanate (IPDI) in terms of the scratch resistance. A content of the HDI or IPDI in the component B2 may be in a range of 80 to 100 wt %, or in a range of 90 to 100 wt %, with respect to the total mass of the component B2.

The ratio of the component B2 in the polyurethane resin X2 is not particularly limited as long as the component B2 has effects according to the present disclosure. In some embodiments, the molar ratio of the total amount of the NCO group of the component B2 to the total amount of the active hydrogen group in the component A2 (total molar amount of NCO group of the component B2/a total molar amount of active hydrogen group in the component A2) may be in a range of 1.00 to 1.10, or in a range of 1.00 to 1.05. When the molar ratio is in a range of 1.00 to 1.10, the scratch resistance may be enhanced.

(Method of Preparing a Polyurethane Resin X2)

A method of preparing a polyurethane resin X2 according to this embodiment is not particularly limited, and the polyurethane resin X2 may be prepared in the same manner as described for the polyurethane resin X1, except that the component A2 and the component B2 are used.

As measured by a method that will be described later, the elastic recovery rate when the polyurethane resin X2 is 100% stretched is in a range of 80 to 100%. When the elastic recovery rate when the polyurethane resin X2 is 100% stretched is within this range, a base material layer having a high recovery force may be obtained, and the pencil hardness of the cover film may be improved.

In this embodiment, the elastic recovery rate with 100% stretched may be measured using the following method.

<Method of Measuring an Elastic Recovery Rate with 100% Stretched>
(1) A sheet having a film thickness of approximately 2 mm is prepared using the polyurethane resin X1 or the polyurethane resin X2. The sheet is cut into elongate rectangular test specimens with a size of 100 mm×5 mm (width×length), and scale marks are displayed on the sheet so that distances between the scale marks are 50 mm.
(2) This test specimen is set in a jig of an Instron-type tensile tester (product name: “Autograph” commercially available from Shimadzu Corporation), and stretched at a constant rate of 500 mm/min under an atmosphere of 25° C. until the distance between the scale marks reaches 100%, and a manipulation of returning the distance between the scale marks to that before the stretching is immediately performed.
(3) The stress (M1) when 50% stretched in the stretching process and the stress (M2) when 50% stretched in the returning process while performing this manipulation are measured to calculate an elastic recovery rate using the following Equation 2.

Elastic recovery rate (%)=M2/M1*100 [Equation 2]

(Other Components (C2))

The base material layer may include other component C2 (hereinafter referred to as component C2) in addition to the polyurethane resin X2. For example, the component C2 may include the same components as the above-described components C1. Among them, the environmental stabilizing agent may be included as the component C2 in terms of easily controlling the deterioration (discoloration and the like) of the cover film with elapsed time and further improving the light fastness and heat resistance as well.

A content of the environmental stabilizing agent in the base material layer may be in a range of 0.5 to 5.0 wt %, in a range of 1.0 to 5.0 wt %, or in a range of 1.5 to 5.0 wt %, with respect to the total mass of the resin composition constituting the base material layer. When the content of the environmental stabilizing agent in the base material layer is greater than or equal to 0.5 wt %, a cover film with less thermally deterioration as time passes may be easily obtained. Also, when the content of the environmental stabilizing agent in the base material layer is less than or equal to 5.0 wt %, the yellowing of the film by the environmental stabilizing agent may be suppressed with excellent light fastness and heat resistance of the cover film. Also, when the base material layer comprises the above-described polyurethane resin X2 and the environmental stabilizing agent without the component C2, the content of the environmental stabilizing agent in the base material layer is the ratio relative to the sum (100 wt %) of the polyurethane resin X2 and the environmental stabilizing agent.

In some embodiments of the present disclosure, the sum of the component C1 and the component C2 included in the cover film may be in a range of 0.5 to 5.0 wt %, may be in a range of 1.0 to 5.0 wt %, and may also be in a range of 1.5 to 5.0 wt %, with respect to the total mass of the entire resin composition constituting the cover film. When the sum of the component C1 and the component C2 included in the cover film is within this range, a cover film with less thermally deterioration as time passes may be easily obtained.

[Method of Preparing a Cover Film]

A method of preparing a cover film according to this embodiment is not particularly limited. In some embodiments, the cover film may, for example, be prepared using a method which includes: preparing a prepolymer for a polyurethane resin X1 and a prepolymer for a polyurethane resin X2 (Process (i)); coating (plating) the prepolymer for the polyurethane resin X1 on a release film to form a surface layer having a predetermined film thickness (Process (ii)); and coating the prepolymer for the polyurethane resin X2 on the surface layer to form a base material layer having a predetermined film thickness (Process (iii)). Hereinafter, the preparation method including the processes (i) to (iii) will be described.

<Process (i)>

Process (i) is a process of preparing the prepolymer for the polyurethane resin X1 and the prepolymer for the polyurethane resin X2.

The prepolymer for the polyurethane resin X1 is a compound that has a hydroxyl group at the end thereof, and may be prepared by reacting the component A1 including the compound a1-1 and the component B1 optionally in an organic solvent. A hydroxyl value in the prepolymer for the polyurethane resin X1 may be in a range of 2.5 to 10.0 mg KOH/g in the composition from which the solvent is removed.

The prepolymer for the polyurethane resin X2 is a compound that has an isocyanate group at the end thereof, and may be prepared by reacting the component A2 and the component B2 optionally in an organic solvent. An amount of an isocyanate residue in the prepolymer for the polyurethane resin X2 may be in a range of 2.0 to 6.0% in the composition from which the solvent is removed.

A catalyst may be optionally used to promote the reaction while preparing the polyurethane resins X1 and X2. For example, specific examples of the catalyst include organic metal compounds, e.g., dibutyltin dilaurate, dioctyltin dilaurate, bismuth carboxylate, bismuth alkoxides, or chelate compounds of bismuth with compounds having a dicarbonyl group, inorganic metal compounds, e.g., bismuth oxides, bismuth hydroxides or bismuth halides, tertiary amines, e.g., triethylamine, triethylenediamine or 1,8-diazabicyclo[5.4.0]-7undecene, and may be used in combinations of two or more.

The reaction temperature for preparing the urethane prepolymers for the polyurethane resin X1 or X2 may be in a range of 50 to 140° C., and may also be in a range of 70 to 100° C. Also, the reaction time may be in a range of 1 to 10 hours, and may also be in a range of 2 to 8 hours.

<Process (ii)>

The process (ii) is a process of forming the surface layer. In the process (ii), the surface layer is formed by mixing the urethane prepolymer for the polyurethane resin X1 or an organic solvent solution thereof optionally with the above-mentioned high-molecular polyol, the above-mentioned component a1-2, such as a chain extending agent and the like, and the above-mentioned component C1, such as an environmental stabilizing agent and the like, and coating (plating) the resulting mixture with a predetermined film thickness on the release film. The thickness of the surface layer may be less than or equal to 10 μm, or in a range of 3 to 8 μm, in terms of the scratch resistance and optical properties. Also, when the organic solvent solution of the prepolymer for the polyurethane resin X1 is used, the process (ii) may further include a process of drying the organic solvent. The drying temperature may be in a range of 30 to 160° C., and may also be in a range of 100 to 150° C. The drying time may be in a range of 10 seconds to 5 minutes, and may also be in a range of 20 to 60 seconds.

<Process (iii)>

The process (iii) is a process of forming the base material layer. In the process (iii), the base material layer is formed by mixing the urethane prepolymer for the polyurethane resin X2 or an organic solvent solution thereof optionally with the above-mentioned component a2-2, such as a chain extending agent and the like, and the above-mentioned component C2, such as an environmental stabilizing agent and the like, and coating (plating) resulting mixture with a predetermined film thickness on the surface layer, which is obtained in the process (ii). The process (iii) may further include a process of thermally curing after the process of coating (plating) the urethane prepolymer for the polyurethane resin X2 or the organic solvent solution thereof on the surface layer. The curing temperature may be in a range of 60 to 150° C., and may also be in a range of 80 to 120° C. The curing time may be in a range of 1 to 8 hours, and may also be in a range of 2 to 6 hours.

Also, when the organic solvent solution of the prepolymer for a polyurethane resin X2 is used, the process (iii) may further include a process of drying the organic solvent. The process of drying the organic solvent may be performed with the curing process.

The thickness of the base material layer may be greater than or equal to 150 μm, or in a range of 150 to 450 μm, in terms of the mechanical properties.

The cover film according to this embodiment may be prepared using the preparation method including the processes (i) to (iii).

The total light transmittance of the cover film according to this embodiment when 50% stretched may be greater than or equal to 85%, or greater than or equal to 90%. Also, the haze value of the cover film may be less than or equal to 5%, or less than or equal to 1%. As described above, since the cover film is used as a surface protection film of an image display device, high transparency is desired. When the total light transmittance of the cover film is greater than or equal to 90% and the haze value is also less than or equal to 1% with 50% stretched, the transparency of the cover film is not easily degraded even when the image display device having the cover film according to this embodiment is stretched or folded.

As measured according to Japanese Industrial Standards (JIS) K 6400-2, the hysteresis loss ratio of the cover film according to some embodiments may be less than or equal to 12%, less than or equal to 10%, or less than or equal to 8%. When the hysteresis loss ratio is less than or equal to 12%, the response and durability may be easily enhanced when the image display device having the cover film according to this embodiment is deformed.

[Image Display Device]

The image display device according to some embodiments of the present disclosure includes the cover film, the image display element, and the substrate, e.g., the stretchable substrate or the flexible substrate. The image display element is disposed between the cover film and the substrate. In other words, the image display device according to some embodiments of the present disclosure is characterized in that the cover film, the image display element, and the stretchable substrate or the flexible substrate are sequentially stacked. The image display device according to some embodiments of the present disclosure may be used as a flexible display and/or stretchable display because the image display device has excellent scratch resistance, mechanical properties, optical properties, and stretchability. That is, the image display device according to some embodiment of the present disclosure may have flexibility and/or stretchability.

<Image Display Element>

In this specification, the term “image display element” refers to a display element that has a display medium having varying contrast, brightness, reflectance, transmittance, and the like by an electrical action or magnetic action. Examples of the display element include electroluminescence (EL) elements, LED chips (white LED chips, red LED chips, green LED chips, blue LED chips, and the like), liquid crystal elements, and the like.

<Flexible Substrate>

In this specification, the term “flexible substrate” refers to a substrate which is bendable, foldable, windable, and the like. In some embodiments of the present disclosure, the flexible substrate may include a resin material such as a polyimide, polyethylene terephthalate, polyethylene naphthalate, polycarbonate, and the like, but the present disclosure is not limited thereto.

<Stretchable Substrate>

In this specification, the term “stretchable substrate” refers to a substrate that is stretchable. In some embodiments of the present disclosure, the stretchable substrate may include a silicone rubber, such as polydimethylsiloxane and the like, or an elastomer, such as polyurethane, polytetrafluoroethylene (PTFE), and the like, but the present disclosure is not limited thereto.

<Other Configurations>

The image display device according to some embodiments of the present disclosure may further include a touch panel or a sensor element.

[Method of Preparing an Image Display Device]

A method of preparing the image display device according to some embodiments of the present disclosure may include a process of directly attaching the cover film according to this embodiment onto the image display element.

### EXAMPLES

Hereinafter, the present disclosure will be described in further detail with reference to exemplary embodiments thereof, but the present disclosure is not limited to these exemplary embodiments.

Materials used in examples and comparative examples are as described below.

[Polyurethane Resin X1: PU-X1]

<Active Hydrogen Component A1>

(Compound a1-1)
Compounds having a polyorganosiloxane as the backbone structure and amino groups at both ends of the molecular chain thereof (product name: “BY-16-853U™” commercially available from Toray Dow Corning Co., Ltd. or product name: “KF-8012™” commercially available from Shin-Etsu Chemical Co., Ltd.).

(Component a1-2)
High-molecular polyol: Polycarbonatediol (product name: “DURANOL T4671™” commercially available from Asahi Kasei Corporation).
Chain extending agent: 1,4-butandiol and water.
Reaction stopping agent: Diethanolamine.

<Non-Yellowing-Type Polyisocyanate Component B1>
Alicyclic polyisocyanate (hydrogenated MDI).
Compound b1: Allophanate-modified HDI™ (product name: “CORONATE-2793™” commercially available from Tosoh Corporation).

[Polyurethane Resin X2: PU-X2]

<Active Hydrogen Component A2>

(Component a2-1)
Polytetramethylene ether glycol (product name: “PTMG-2000 ™” commercially available from Mitsubishi Chemical Corporation; Mn=2,000).
Polytetramethylene ether glycol (product name: “PTMG-1000 ™” commercially available from Mitsubishi Chemical Corporation; Mn=1,000).
Polyoxypropylene sorbitol ether (product name: “SANNIX® SP-750” commercially available from Sanyo Chemical Industries, Ltd.).

(Component a2-2)
Chain extending agent: 1,4-butanediol

<Non-Yellowing-Type Polyisocyanate Component B2>
Hexamethylene diisocyanate

[PU-1]
Polyurethane resin obtained by reacting a main material including the following lubricant with a curing agent.
Main material: A prepolymer being a reaction product of polyisocyanate with a polyol including a polycarbonate polyol and having a hydroxyl group at the end thereof.
Lubricant: Silicone compound.
Curing agent: Polyisocyanate compound.

[PU-2]
Two-components curing type urethane resin.

[PU-3]
Polyurethane resin obtained by reacting a main material including the following lubricant with a curing agent.
Main material: A prepolymer being a reaction product of polyisocyanate with a polyol and having a hydroxyl group at the end thereof.
Lubricant: Silicone compound.
Curing agent: Polyisocyanate compound.

[PDMS]
Copolymer of polydimethylsiloxane obtained by reacting the following α and β agents with a ratio of 1:1 and having a siloxane bond in the molecule.
α agent: A vinyl group-containing polydimethylsiloxane including a platinum catalyst.
β agent: A composition including a vinyl group-containing polydimethylsiloxane, a curing agent, and a reaction inhibitor.

[Component C1]
Environmental stabilizing agent: It is obtained by mixing an ultraviolet absorbent (a benzotriazole compound (product name: “TINUVIN ° 329” commercially available from BASF Japan Ltd.)), an antioxidant (a hindered phenol compound (product name: Irganox® 245″ commercially available from BASF Japan Ltd.)), and a light stabilizing agent (a hindered amine compound (product name: “TINUVIN 144 ™” commercially available from BASF Japan Ltd.)) at a ratio of 1:4:16.

[Component C2]
Environmental stabilizing agent: It is obtained by mixing an ultraviolet absorber (a benzotriazole compound (product name: “TINUVIN 329 ™” commercially available from BASF Japan Ltd.)), an antioxidant (a hindered phenol compound (product name: “Irganox 245 ™” commercially available from BASF Japan Ltd.)), and a light stabilizing agent (a hindered amine compound (product name: “TINUVIN 144™” commercially available from BASF Japan Ltd.)) at a ratio of 1:11:45.

### Example 1

The component C1 was added to an organic solvent solution of the prepolymer for the polyurethane resin X1, and mixed. The mixture was coated (plated) on a release film to have a thickness of the mixture was 5 μm. Thereafter, the release film was dried at 145° C. for 5 minutes to form a semi-cured surface layer. The component C2 was added to the prepolymer for the polyurethane resin X2, and mixed. The mixture was coated (plated) on the semi-cured surface layer so that the cover film has a total thickness of 400 μm. The base material layer and the surface layer were cured at 145° C. for 2 hours, and then cured at 80° C. for 24 hours to manufacture the cover film in which the base material layer and the surface layer were chemically bonded to each other. A composition of the polyurethane resin (X1: PU-X1) constituting the surface layer of the cover film and a composition of the polyurethane resin (X2: PU-X2) constituting the base material layer of the cover film are as described in Table 1. In the PU-X1, the ratio of the compound a1-1 to the sum of the component A1 and the component B1 was 1.75 wt %. Also, the ratios of the component C1 and the component C2 in the surface layer and the base material layer were as described in Table 2.

Also, as measured under the following conditions, the elastic recovery rates of the PU-X1 and PU-X2 when 100% stretched were 63% and 85% for the PU-X1 and PU-X2, respectively.

<Method of Measuring Elastic Recovery Rate when 100% Stretched>
(1) A sheet having a film thickness of 2 mm was prepared using the polyurethane resin X1 or the polyurethane resin X2. The sheet was cut into elongate rectangular test specimens with a size of 100 mm×5 mm (width×length), and scale marks were displayed on the sheet so that the distances between the scale marks were 50 mm.
(2) This test specimen was set in a jig of an Instron-type tensile tester (product name: “Autograph” commercially available from Shimadzu Corporation), and stretched at a constant rate of 500 mm/min under an atmosphere of 25° C. until the distance between the scale marks reached 100%, and a manipulation of returning the distance between the scale marks to that before the stretching was immediately performed.
(3) The stress (M1) when 50% stretched in the stretching process and the stress (M2) when 50% stretched in the returning process while performing this manipulation were measured to calculate an elastic recovery rate from the following Equation 2.

Elastic recovery rate (%)=M2/M1*100 [Equation 2]

The tacking properties, texture, optical properties, rupture properties, scratch resistance, mechanical properties, and environmental properties (deterioration as time passes) of the cover film obtained in Example 1 were evaluated under the following conditions. The results are listed in Table 2.

<Tacking Properties and Texture of Cover Film>

(Tacking Properties)

A test was carried out according to ASTM D2979, and surface tack less than or equal to 0.01 N was considered satisfactory.

(Texture)

A contact angle scale was slid with a size of 15 mm×10 mm of the surface layer of the cover film at a load of 20 gf and a speed of 1 mm/s using a static/dynamic friction measuring machine (product name: “TL201Tt” commercially available from Trinity-Lab. Inc.) to measure dynamic friction and static friction coefficients, which were then evaluated under the following evaluation criteria.

(Evaluation Criteria)
Pass: The dynamic friction and static friction coefficients were less than or equal to the value measured for water-white glass (product name: “Eagle XG®” commercially available from Corning Incorporated).
Fail: The dynamic friction and static friction coefficients were greater than the value measured for water-white glass (product name: “Eagle XG™” commercially available from Corning Incorporated).

<Optical Properties: Measurement of Total Light Transmittance and Haze Value>

The total light transmittance and haze value of the resulting cover film when 0% stretched (not stretched), when 50% stretched, and when released were measured using a spectrum colorimeter (product name: “CM3600V™” commercially available from Konica Minolta, Inc.). Also, the expression “when 50% stretched” refers to a value that is measured in a state in which a sample of the resulting cover film was elongated 1.5-fold. Also, the expression “when released” refers to a value that is measured immediately after the release of the cover film after being 50% stretched.

<Rupture Properties: Measurement of Hysteresis and Hysteresis Loss Ratio>

The hysteresis and hysteresis loss ratio of the resulting cover film were measured according to JIS K 6400-2.

<Scratch Resistance: Steel-Wool Test>

Steel wool #0000 was reciprocated on one side of the surface layer of the cover film at a pressure of 75 gf/cm 2 and a speed of 40 mm/s to evaluate a friction degree (the presence of scars or sliding tracks) of the cover film according to the following evaluation criteria. Also, the following number of reciprocations represents the number of reciprocations in which no scars or sliding tracks are generated on the cover film.

(Evaluation Criteria)
S: The number of reciprocations is greater than or equal to 1,000.
A: The number of reciprocations is 500 or more to less than 1,000.
B: The number of reciprocations is 250 or more to less than 500.
C: The number of reciprocations is 50 or more to less than 250.
D: The number of reciprocations is less than 50.

<Mechanical Properties: Pencil Hardness>

The cover film was fixed onto a glass substrate, and the surface layer of the cover film was heavily pushed down with pencil lead at a load of 750 gf. In this state, the pencil was allowed to move at a speed of 300 mm/min to evaluate the scratch hardness of the cover film as the hardness of the pencil lead. Also, the cover film was fixed onto the glass substrate without any adhesive, and the evaluation was then carried out.

<Stretchability: Heat Resistance Test>

Paper was stacked on the cover film, rolled up to be attached to the surface layer of the cover film, and then stored at 95° C. for 300 hours. Thereafter, the cover film was cooled to the room temperature to check with the naked eye whether the paper was attached to the surface layer of the cover film, and evaluated according to the following evaluation criteria

(Evaluation Criteria)
Pass: The paper did not peel off when the cover film returned to its original shape, and did not attach to the surface layer of the cover film.
Fail: The paper was ripped when the cover film returned to its original shape, and attached to the surface layer of the cover film.

### Comparative Examples 1 to 3

Cover films were prepared using the resins listed in Table 2. In Comparative Example 1, a cover film was also prepared in the same manner as in Example 1, except that the resin shown in Table 2 was used. In Comparative Example 3, an α agent and a β agent were mixed at a ratio of 1:1, the mixture was coated on a release film, and the coated release film was cured at 130° C. for 5 minutes to prepare a cover film (a PDMS film) composed only of the surface layer. In Comparative Example 2, the PDMS film of Comparative Example 3 was treated with corona discharge, coated with PU-3, and then cured at 80° C. for 1 hour to prepare a cover film. Then, the tacking properties, texture, optical properties, rupture properties, scratch resistance, mechanical properties, and stretchability of the cover film of each of the comparative examples were evaluated in the same manner as in Example 1 according to the following conditions. The results are listed in Table 2.

### Reference Example 1

For the cover film of Example 1, samples in which the contents of the component C1 and the component C2 in the surface layer and the base material layer were 0 wt % (including none of components C1 and C2), 1.5 wt %, 3 wt %, and 5 wt % with respect to the resin composition constituting each layer were prepared, and an environmental test was carried out according to the following conditions. As a result, the samples in which the contents of the components C1 and C2 were 0 wt % had a ΔY1 (a yellowing index) of more than 10, and the films were yellowed. Meanwhile, in the samples including 1.5 to 5 wt % of the components C1 and C2, the ΔY1 was in a range of approximately 1.2 to 2.4, and the films were not discolored. From these results, it was confirmed that the deterioration of the cover film with the passage of time was easily suppressed by blending a predetermined amount of the components C1 and C2 (an environmental stabilizing agent) into the surface layer and the base material layer.

<Environmental Test>

The samples of the cover films were stored under the conditions of a temperature of 65° C. and a humidity of 60% RH for 240 hours under a metal halide lamp with a power density of 830 W/m 2. After the storage, the ΔY1 (a yellowing index) of the cover film was measured using a spectrum colorimeter (product name: “CM3600A” commercially available from Konica Minolta, Inc.).

TABLE 1

| | | | | PU-X1 | PU-X2 |
|---|---|---|---|---|---|
| | | | | Polyurethane | Polyurethane |
| | | | | resin X1 | resin X2 |
| Active hydrogen | Compounds | BY-16-853U | (parts by | 1.50 | — |
| components (A1) | (a1-1) | KF-8012 | weight) | 0.25 | — |
| | Components | T4671 | | 66.2 | — |
| | (a1-2) | 1,4-Butanediol | | 1.6 | — |
| | | Water | | 0.4 | — |
| | | Diethanolamine | | 0.4 | — |
| Active hydrogen | Components | PTMG-1000 | | — | 17.3 |
| components (A2) | (a2-1) | PTMG-2000 | | — | 57.7 |
| | | Sp-750 | | — | 7.9 |
| | Components | 1,4-Butanediol | | — | 1.2 |
| | a2-2 | | | | |

| Polyisocyanate components (B1) | MDIH | 27.7 | — |
|---|---|---|---|
| | CORONATE-2793 | 2.0 | — |
| Polyisocyanate components (B2) | HDI | — | 15.9 |

| | | | |
|---|---|---|---|
| Ratio of compounds (a1-1) to sum of components (A1) and | (wt %) | 1.75 | — |
| components (B1) | | | |
| Crosslinking point concentration | (mmol/g) | 0.045 | 0.45 |
| Elastic recovery rate when 100% stretched | (%) | 63 | 85 |

TABLE 2

| | | | | | Example | Example | Example | Example |
|---|---|---|---|---|---|---|---|---|
| | | | | | 1 | 2 | 3 | 4 |
| Cover | Surface | PU-X1 | | (wt %) | 1.29 | — | — | — |
| film | layer | PU-1 | | | — | 2.5 | — | — |
| (blend) | | PDMS | | | — | — | 2.5 | 100 |
| | | Component C1 | | | 0.01 | — | — | — |
| | Base | PU-X2 | | | 97.2 | | | |
| | material | PU-2 | | | | 97.5 | | |
| | layer | PU-3 | | | | | 97.5 | |
| | | Component C2 | | | 1.5 | | | |
| | Limit amount of entire resin composition | | | | | | 100 | 100 |
| Molecular | Molecular structure of | | Urethane bond | (—) | O | O | O | — |
| structure | surface layer | | Urea bond | | O | — | — | — |
| and | | | Polyorganosiloxane | | O | O | O | — |
| properties | | | group | | (inner | (added) | (inner | |
| | | | | | bond) | | bond) | |
| | Molecular structure of base | | Urethane bond | | O | O | — | — |
| | material layer | | Siloxane bond | | — | — | O | O |
| | Thickness of cover film | | Surface layer | (μm) | 5 | 10 | 5 | — |
| | | | Base material | | 395 | 390 | 200 | 200 |
| | | | layer | | | | | |
| | | | Thickness | | 400 | 400 | 205 | 200 |
| Evaluation | Optical | Total light | When 0% | (%) | 92.2 | 92.3 | 92.1 | 93.5 |
| results | properties | transmittance | stretched | | | | | |
| | | | When 50% | | 92.2 | 92.3 | 92.2 | 93.8 |
| | | | stretched | | | | | |
| | | | When released | | 92.2 | 92.3 | 92.4 | 93.5 |
| | | Haze value | When 0% | | 0.9 | 0.4 | 1.7 | 0.8 |
| | | | stretched | | | | | |
| | | | When 50% | | 0.6 | 0.3 | 3.0 | 0.7 |
| | | | stretched | | | | | |
| | | | When released | | 0.9 | 0.5 | 1.8 | 0.8 |

| | | | | | | |
|---|---|---|---|---|---|---|
| Rupture | Hysteresis | (mJ) | 4.4 | 43.56 | 5.31 | 2.7 |
| properties | Hysteresis loss ratio | (%) | 3.7 | 33.83 | 20.45 | 12.3 |
| Abrasion | Steel-wool test | (—) | S | B | C | D |
| resistance | | | | | | |
| Mechanical | pencil hardness | | 7H | 8H | <4H | N.D. |
| properties | | | | | | |
| Stretchability | Heat resistance test | | Pass | Fail | Fail | N.D. |
| Others | Tacking properties | | Pass | Pass | Pass | Fail |
| | Texture | | Pass | Pass | Pass | Fail |

The symbol “-” in Tables 1 and 2 means that the corresponding components (or exemplary bonds) are not included.

As shown in Table 2, the cover film of Example 1 satisfying the configuration of this embodiment had excellent scratch resistance, mechanical properties, and optical properties and also had good stretchability. Meanwhile, in the cover films of Comparative Examples 1 to 3 which did not satisfy the configuration of this embodiment, any one of the scratch resistance, mechanical properties, optical properties, and stretchability was poor. From the above results, it was confirmed that the cover film according to this embodiment had excellent scratch resistance, mechanical properties, and optical properties, and also had excellent stretchability. Also, in the image display device having the cover film according to this embodiment, the film was not broken or ruptured even when the device was stretched or folded.

According to the present disclosure, a cover film that has excellent scratch resistance, mechanical properties, and optical properties and also has excellent stretchability, and an image display device including the cover film can be provided.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented with other components or their equivalents. Accordingly, other implementations are within the scope of the following claims.

What is claimed is:

1. A cover film, comprising:
a base material layer; and
a surface layer disposed on at least one surface of the base material layer,
wherein the base material layer and the surface layer are chemically bonded to each other,
wherein the surface layer includes a polyurethane resin X1 having urethane and urea units and a polyorganosiloxane group,
wherein the polyurethane resin X1 is obtained by reacting a non-yellowing isocyanate component B1 with an active hydrogen component A1,
wherein the active hydrogen component A1 includes a compound a1-1 containing the polyorganosiloxane group and an active hydrogen group, and a ratio of the compound a1-1 to a sum (100 wt %) of the active hydrogen component A1 and the non-yellowing isocyanate component B1 is less than or equal to 4.0 wt %,
wherein the base material layer includes a polyurethane resin X2 having a urethane unit,
wherein the polyurethane resin X2 is obtained by reacting a non-yellowing isocyanate component B2 with an active hydrogen component A2 which does not comprise the compound a1-1,
wherein a crosslinking point concentration of the polyurethane resin X2 calculated using Equation 1 is greater than or equal to 0.4 mmol/g,
Crosslinking point concentration (mmol/g)=(F−2)*(mmol of monomer having three or more functional groups in 1 g of the polyurethane resin X2), [Equation 1]
wherein in Equation 1, F denotes a number of functional groups in the monomer having three or more functional groups, and
wherein an elastic recovery rate of the cover film when 100% stretched is in a range of 80% to 100%.

2. The cover film of claim 1, wherein the active hydrogen group in the compound a1-1 comprises at least one group selected from a hydroxyl group, an amino group and a carboxyl group.

3. The cover film of claim 1, wherein the surface layer and the base material layer include an environmental stabilizing agent in a range from 0.5 to 5.0 wt % with respect to a total weight of the surface layer and the base material layer, respectively.

4. The cover film of claim 1, wherein the non-yellowing isocyanate component B1 includes an isocyanate compound b1 having three or more functional group.

5. The cover film of claim 1, wherein the surface layer has a thickness of 10 μm or less, and the base material layer has a thickness of 150 μm or more.

6. The cover film of claim 1, wherein the cover film has a total light transmittance of 85% or more and a haze value of 5% or less when 50% stretched.

7. The cover film of claim 1, wherein the cover film has a hysteresis loss ratio of 12% or less, as measured according to Japanese Industrial Standard (JIS) K 6400-2.

8. An image display device comprising:
a stretchable substrate or a flexible substrate;
an image display element disposed on the stretchable substrate or a flexible substrate; and
the cover film of claim 1 disposed on the image display element.

9. The image display device of claim 8, the active hydrogen group in the compound of a1-1 comprises one group selected from a hydroxyl group, an amino group and a carboxyl group.

10. The image display device of claim 8, wherein the surface layer and the base material layer include an environmental stabilizing agent in a range of 0.5 to 5.0 wt % with respect to a total weight of the surface layer and the base material layer, respectively.

11. The image display device of claim 8, wherein the non-yellowing isocyanate component B1 includes the isocyanate compound b1 having three or more functional group.

12. The image display device of claim 8, wherein the surface layer has a thickness of 10 μm or less, and the base material layer has a thickness of 150 μm or more.

13. The image display device of claim 8, wherein the cover film has a total light transmittance of 85% or more and a haze value of 5% or less when 50% stretched.

14. The image display device of claim 8, wherein the cover film has a hysteresis loss ratio of 12% or less, as measured according to JIS K 6400-2.

15. The image display device of claim 8, wherein the image display device has flexibility and/or stretchability.

16. The cover film of claim 1, wherein the non-yellowing isocyanate component B1 is an isocyanate which does not include an aromatic component.

17. The cover film of claim 1, wherein the base material layer and the surface layer are chemically bonded to each other through a reaction between a component in the surface layer and a component in the base material layer at least at an interface between the base material layer and the surface layer.
